(19) United States
(12) Patent Application Publication
(10) Pub. No.: US 2025/0264575 A1
(43) Pub. Date: Aug. 21, 2025

(54) RADAR SENSOR HAVING A WAVEGUIDE STRUCTURE

(71) Applicant: Robert Bosch GmbH, Stuttgart (DE)

(72) Inventors: Juergen Seiz, Welzheim (DE); Christian Hollaender, Rheinstetten (DE); Kai Schiemenz, Stuttgart (DE); Kevin Stella, Ditzingen (DE); Klaus Baur, MIETINGEN (DE); Minh Nhat Pham, Leinfelden-Echterdingen (DE); Stefan Orasch, Remseck (DE); Ulrich Mack, Guenzburg (DE); Vincent Tom Engl, Ludwigsburg (DE)

(21) Appl. No.: 18/857,214

(22) PCT Filed: May 9, 2023
(86) PCT No.: PCT/EP2023/062246

§ 371 Date: Oct. 16, 2024

(30) Foreign Application Priority Data
Jun. 29, 2022 (DE) 10 2022 206 584.0

(51) Int. Cl. G01S 7/03; G01S 13/931

(52) U.S. Cl. CPC G01S 7/032; G01S 13/931

(57) ABSTRACT

A radar sensor. The radar sensor has a plate-like substrate which has at least one layer composed of electrically non-conductive material and on one side has a waveguide structure and on the opposite side has a radiofrequency source/sink, which is connected to the waveguide structure via a radiofrequency bushing which passes through the substrate. A wall of the radiofrequency bushing is formed by a sequence of circular-cylindrically curved surface segments which have a uniform cross section over at least part of the length of the radiofrequency bushing.

### FIELD

The present invention relates to a radar sensor having a plate-like substrate which has at least one layer composed of electrically non-conductive material and on one side has a waveguide structure and on the opposite side has a radiofrequency source/sink, which is connected to the waveguide structure via a radiofrequency bushing which passes through the substrate.

In particular, the present invention relates to a radar sensor for motor vehicles.

### BACKGROUND INFORMATION

Radar sensors are used in motor vehicles to implement comfort functions such as adaptive cruise control and safety functions such as emergency braking assistants. The radar sensors emit radiofrequency radar beams via an antenna structure and receive the beams reflected from objects. The detected objects can be stationary or moving. With the aid of the received radar beams, the distance and direction (angle) to the object can be calculated. In addition, the velocity of the object relative to the radar sensor can be calculated.

Radar sensors typically operate in a frequency range between 76 and 81 GHZ.

Driver assistance functions with higher functionality in the field of comfort or safety, such as NCAP AEB emergency braking functions for pedestrians or cyclists, as well as future autonomous functions in the Level 3 to Level 5 range, result on the one hand in a large number of sensors that have to be arranged around the vehicle in different positions in order to cover the necessary field of vision, and on the other hand in sensors with an ever wider azimuthal detection region.

Radar sensors with a wide azimuthal detection region and a long range can be realized by using waveguide antennas, among other things. The waveguide antenna can be fed via a metallized opening through a circuit board so that the waveguide antenna and a radio frequency source (or a radio frequency sink, i.e., a receiver) can be arranged on opposite sides of the circuit board. It is conventional to produce such openings in the circuit board, which serve as radiofrequency bushings, by drilling or milling into the circuit board a through-hole with the desired cross section and then metallizing the circuit board including the surface of the through-hole using a standard process.

### SUMMARY

An object of the present invention is to provide a radar sensor with a radiofrequency bushing which has a geometry optimized for the relevant application and can nevertheless be produced cost-effectively.

This object may be achieved according to the present invention in that a wall of the radiofrequency bushing is formed by a sequence of circular-cylindrically curved surface segments which have a uniform cross section over at least part of the length of the radiofrequency bushing.

These radiofrequency bushings can be produced cost-effectively in any desired cross sectional shape by arranging holes in a row, the cross sections of which overlap or at least almost touch each other, so as to correspond to the course of the wall of the radiofrequency bushing. Although the wall thus formed of the radiofrequency bushing does have a certain waviness because each individual hole forms at least one circular-cylindrically curved segment of the wall, it is however possible with a relatively small number of holes and with correspondingly little effort to ensure that for microwaves the waviness has no adverse effect on the transmission properties of the radiofrequency bushing, especially if the wall unevenness is smoothed out by subsequent metallization.

A major advantage of this production process is that no complex milling process is required to realize a desired geometry of the radiofrequency bushing which deviates from the circular shape. The holes can be efficiently made with a single drill or an assortment of a few drills and can be arranged in such a way that only low transverse forces act on the drill during the drilling process.

The present invention also relates to a method for producing a radar sensor with the features specified above, in which the radiofrequency bushing is formed by arranging a plurality of holes in a row corresponding to the course of the wall of the radiofrequency bushing that is to be produced.

Advantageous example embodiments and developments of the present invention are disclosed herein.

According to an example embodiment of the present invention, the holes can be made in the substrate in such a way that their cross sections overlap each other, i.e., that the distance between the axes of two adjacent holes is less than the diameter of the holes or, if these diameters are different, less than the sum of the radii of the two holes. The holes arranged in a row then create a straight or curved slot in the substrate.

In one example embodiment of the present invention, the radiofrequency bushing is formed directly by this slot. In another embodiment, the curved or multi-angled slot forms a closed line. Inside this line, the remaining material of the circuit board then forms an island that is not connected to the surrounding material and therefore drops out, resulting in a radiofrequency bushing of which the width is greater than the width of the slot.

Each individual hole creates a circular-cylindrically curved wall segment in the wall of the radiofrequency bushing, and the adjacent wall segments form a series of ridges along the wall of the radiofrequency bushing that project into the interior of the bushing. The shorter the distance between the axes of the individual holes, the flatter and blunter these ridges will be. Increasing the distance between the axes of the holes results in higher and sharper ridges, but from this the advantage arises that lower transverse forces act on the drill when drilling a single hole because the surfaces at which the drill engages the wall of the substrate are more evenly distributed.

If the distance between the axes of the holes is finally increased to such an extent that it becomes equal to the diameter of the holes, the circular-cylindrical wall segments will form a sequence of semicircles. If the distance between the axes is increased even further, narrow connecting pieces will be left between the individual holes. However, if the slot formed by the holes forms a closed line, the island enclosed by the line, which is then connected to the surrounding material via narrow connecting pieces, can be broken out with little force so that a radiofrequency bushing with a relatively large cross sectional area is obtained with a comparatively small number of holes, in which practically no transverse forces occur.

According to an example embodiment of the present invention, the substrate will generally be a multilayer circuit board having at least two electrically conductive layers on its two opposite surfaces. However, additional electrically conductive layers can optionally be provided inside the circuit board. After one or more radiofrequency bushings have been produced via the process described above, the metallized layers on the two surfaces of the circuit board and the metallized layers on the inner surfaces of the radiofrequency bushings can be produced in a single operation via conventional chemical or electrochemical metallization processes. Preferably, the metallization layer on the inner surfaces of the radiofrequency bushings should have a thickness of 1 μm or more, since in that case the ridges mentioned above will be reliably covered and the radiofrequency properties no longer be dependent on the thickness of the metallization.

Since the method according to the present invention allows a high degree of flexibility with regard to the design of the cross sectional geometry of the radiofrequency bushings, the bandwidth can be optimized in a simple manner, and desired filter or attenuation properties can be realized by a suitable choice of the geometry, possibly even selectively for certain polarization directions. The attenuation properties and permittivity of the radiofrequency bushings can also be influenced by filling the through-holes that form these radiofrequency bushings with suitable materials. If required, additional conductor structures can then be attached to the filling material at the opposite ends of the radiofrequency bushing.

Nor is it necessary for the holes used to create the walls of the radiofrequency bushings to pass from one side of the circuit board to the other. For example, a first contour can be formed by a sequence of shallow holes and then, within the first contour, a further contour can be formed by a sequence of deeper holes, the geometry of which contour is, within certain limits, independent of the geometry of the first contour. In this way, stepped structures can also be realized in the radiofrequency bushing.

In the following, exemplary embodiments of the present invention are explained in more detail with reference to the figures.

### BRIEF DESCRIPTION OF THE DRAWINGS

FIG. 1 shows a partial section through a radar sensor according to an exemplary embodiment of the present invention.

FIG. 2 shows a section through a substrate of the radar sensor according to FIG. 1 and a radiofrequency bushing formed therein.

FIGS. 3 and 4 show examples of radiofrequency bushings with different geometries.

FIG. 5 shows a section through a substrate with a radiofrequency bushing according to another exemplary embodiment of the present invention.

### DETAILED DESCRIPTION OF EXAMPLE EMBODIMENTS

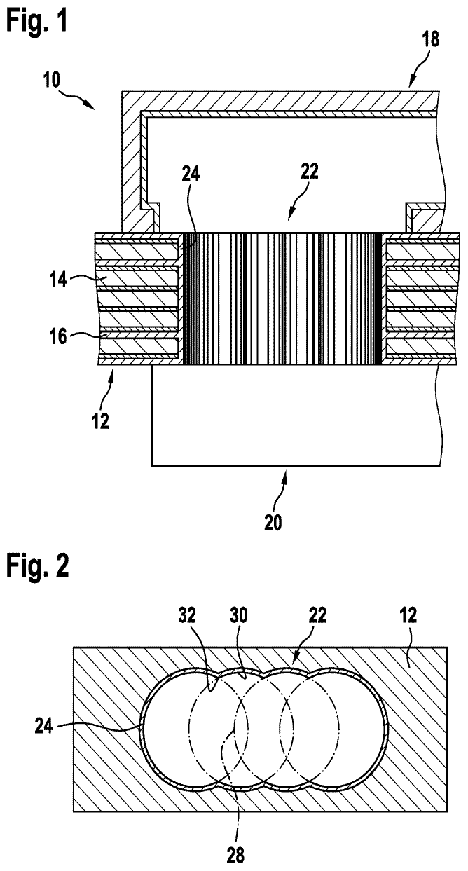

The radar sensor 10 shown in a partial section in FIG. 1 has a substrate 12 which is formed by multiple layers 14 of electrically non-conductive material and, alternating therewith, layers 16 of electrically conductive material. The upper face and lower face of the substrate 12 are metallized and thus also form layers 16 of electrically conductive material.

A waveguide structure 18 is arranged on the upper face of the substrate 12, which can be, for example, a waveguide antenna or a connecting structure that leads to a waveguide antenna (not shown). On the opposite side of the substrate 12, at the bottom in FIG. 1, a radiofrequency source/sink 20 is arranged, which is formed, for example, by an integrated radiofrequency module (MMIC) and serves to generate a microwave signal and feed it into the waveguide structure 18 and/or to detect and evaluate a microwave signal received by the waveguide antenna.

The waveguide structure 18 and the radiofrequency source/sink 20 are connected to each other by a radiofrequency bushing 22 for signal transmission. This radiofrequency bushing 22 is formed by a through-hole which, in the example shown, has a uniform cross section from the upper face to the lower face of the substrate 12 and the wall of which has a metallization 24. The radiofrequency bushing 24 is thus able to transmit microwave signals from a connection point of the waveguide structure 18 to a connection point of the radiofrequency source/sink 20 and vice versa. The transmissivity of the radiofrequency bushing 22 for microwave signals with different frequencies and polarization depends on the geometry, in particular on the cross section of the through-hole that forms the radiofrequency bushing 22.

In FIG. 2, the radiofrequency bushing 22 is shown in cross section. As can be seen, the radiofrequency bushing 22 is formed by four holes 28 arranged in a row, the outlines of which are shown in dash-dotted lines in FIG. 2. The four holes 28 have a uniform radius and are arranged at uniform center distances, with this center distance being slightly less than the diameter of the holes, so that the cross sections of the holes overlap each other. In FIG. 2 the upper and lower walls of the radiofrequency bushing 22 therefore have a wavy cross sectional shape and are formed by circular-cylindrical wall segments 30, each of which corresponds to a part of the circumference of one of the holes 28 and which adjoin one another to form ridges 32.

The radiofrequency bushing 22 thus has overall the shape of an elongate straight slot, the opposite walls of which are formed by diametrically opposed wall segments 30 of the same holes. The radiofrequency bushing can be produced, for example, by clamping the substrate 12 in an X/Y table which enables controlled movements of the substrate in a two-dimensional X/Y plane, and by forming the holes 28 one after the other using a drill clamped in a drill chuck fixed in the X/Y plane. The substrate 12 is then metallized to form the metallization 24 on the walls of the radiofrequency bushing 22 as well as the metallizations on the upper face and lower face of the substrate.

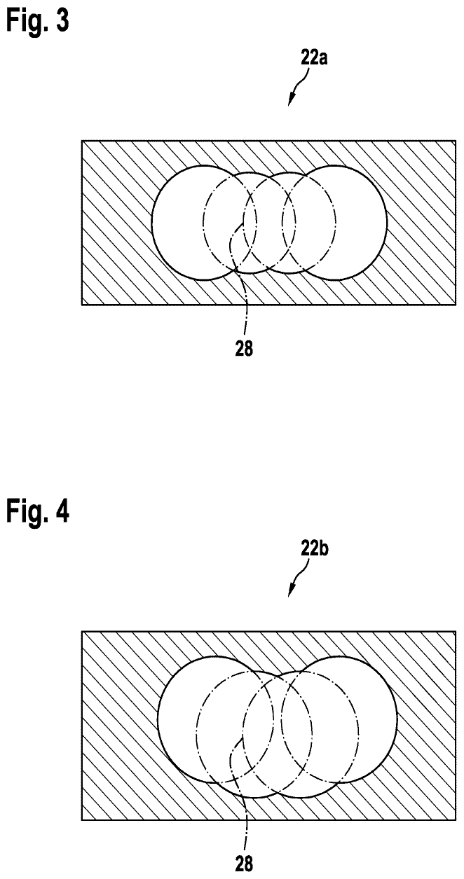

FIG. 3 shows a radiofrequency bushing 22a, which differs from the exemplary embodiment according to FIG. 2 in that the holes 28 have different diameters. In the example shown, the diameters have been selected such that the slot forming the radiofrequency bushing has a waist in the middle and its width increases toward both ends.

FIG. 4 shows a radiofrequency bushing 22b according to a further exemplary embodiment. In this case, the holes 28 once again have a uniform diameter, but their center axes are arranged on a curved line such that the slot forming the radiofrequency bushing overall has a curved shape.

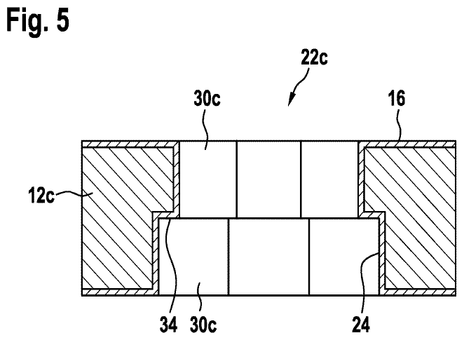

FIG. 5 shows a cross section of a substrate 12c with a radiofrequency bushing 22c stepped in the longitudinal section. This radiofrequency bushing was produced by drilling holes of different diameters into the substrate from opposite sides. The walls of the radiofrequency bushing 22c are therefore delimited by circular-cylindrically curved wall segments 30c, which in FIG. 5 have a shorter radius of curvature and a shorter width in the upper part of the bushing than in the lower part. Accordingly, the center axes of the holes drilled into the substrate from above are spaced closer together than the center axes of the holes drilled from below. Overall, this results in a radiofrequency bushing with a step 34. The contours defined by the wall segments 30c above and below this step can be different from each other.

1-7. (canceled)

8. A radar sensor, comprising:
a plate-like substrate which has at least one layer including electrically non-conductive material and, on one side. has a waveguide structure and on an opposite side, has a radiofrequency source/sink, which is connected to the waveguide structure via a radiofrequency bushing which passes through the substrate;
wherein a wall of the radiofrequency bushing is formed by a sequence of circular-cylindrically curved surface segments which have a uniform cross section over at least part of a length of the radiofrequency bushing.

9. A method for producing a radar sensora plate-like substrate which has at least one layer including electrically non-conductive material and, on one side. has a waveguide structure and on an opposite side, has a radiofrequency source/sink, which is connected to the waveguide structure via a radiofrequency bushing which passes through the substrate;
wherein a wall of the radiofrequency bushing is formed by a sequence of circular-cylindrically curved surface segments which have a uniform cross section over at least part of a length of the radiofrequency bushing, the method comprising:
producing the radiofrequency bushing by arranging in a row a plurality of holes running at right angles to a plane of the substrate, such that the circumferential walls of the holes form the wall segments.

10. The method according to claim 9, wherein the radiofrequency bushing is formed as a slot by the arrangement of the holes in a row, a width of the slot corresponding to a diameter of the holes.

11. The method according to claim 9, wherein axes of the successively produced holes ie on a straight line.

12. The method according to claim 9, wherein the holes have different diameters.

13. The method according to claim 9, wherein the holes are formed all the way from one side of the substrate to the other side of the substrate.

14. The method according to claim 9, wherein the substrate is metallized after the holes have been produced, wherein a metallization with a layer thickness of 1 μm or more is formed on the walls of the radiofrequency bushing.
